(19) United States
(12) Patent Application Publication
(10) Pub. No.: US 2004/0061236 A1
(43) Pub. Date: Apr. 1, 2004

(54) Semiconductor device provided with a dielectric film including porous structure and manufacturing method thereof

(75) Inventor: Tatsuhiko Koide, Anpachi-gun (JP)

Correspondence Address: McDERMOTT, WILL & EMERY, 600 13th Street, N.W., Washington, DC, 20005-3096, US

(73) Assignee: SANYO ELECTRIC CO., LTD.

(21) Appl. No.: 10/669,568

(22) Filed: Sep. 25, 2003

(30) Foreign Application Priority Data
Sep. 30, 2002 (JP) 2002-287672
Aug. 29, 2003 (JP) 2003-307807

(51) Int. Cl. H01L 23/48; H01L 23/52; H01L 29/40

(52) U.S. Cl. 257/760

(57) ABSTRACT

A porous MSQ film 14 is provided on a semiconductor substrate, and a non-porous MSQ film 17 is formed on top of the porous MSQ film 14. A same film material containing Si, O and C is employed in common to form the porous MSQ film 14 and the non-porous MSQ film 17.

This application is based on Japanese patent application NO.2002-287672 and NO.2003-307807, the content of which is incorporated hereinto by reference.

### BACKGROUND OF THE INVENTION

1. Field of the Invention

The present invention relates to a semiconductor device provided with a dielectric film including a porous structure, and to a manufacturing method thereof.

2. Description of the Related Art

As a result of introduction of the design rule on a semiconductor integrated circuit requiring micronization, the problem of interconnection delay has become evident. In an attempt to solve such problem, employment of a porous structure in an interlayer dielectric film has recently been aggressively studied, for achieving a lower dielectric constant. The employment of a porous structure constitutes, together with material selection for an interlayer dielectric film, a key factor in the technique of lowering the dielectric constant.

However, a porous-structured dielectric film often causes insufficient adhesion with an upper or lower adjacent layer. Besides, generally a porous-structured dielectric film lacks in mechanical strength, and is therefore prone to cause a crack or exfoliation. Especially when a load is imposed on a porous film during a CMP (chemical mechanical polishing) process in interconnect formation, the porous film tends to be damaged. In view of these problems, a technique of providing on the porous film a protection layer made of an SiO₂ film, which is easily processible, has been proposed (Proceedings of the IEEE 2002 International Interconnects, 2002.6.3, “CVD Barriers for Cu with Ultra Low-k: Integration and Reliability”, J. C. Lin etc).

The above literature describes an interconnect structure shown in FIG. 1. In this interconnect structure, a lower interconnect 11 is buried in an interconnect dielectric film 12, on which a copper diffusion barrier 13 consisting of SiCN, a low dielectric constant film 40 having a porous structure and a protection layer consisting of SiCN are provided. In these multiple layers, an upper interconnect consisting of a barrier metal 19 and a copper layer 20, and a via plug are formed.

However, such structure does not provide sufficient adhesion between the low dielectric film 40 and the protection layer 18 consisting of SiCN, therefore exfoliation often takes place at an interface of these layers. Besides, a material having a high dielectric constant contained in an upper layer tends to penetrate into a pore of the porous film, thereby increasing a dielectric constant of the porous film.

### SUMMARY OF THE INVENTION

In view of the foregoing problems, it is an object of the present inventionto provide a solution for insufficient adhesion between films, degradation of mechanical characteristics of a dielectric film and complication of manufacturing process of the same and so forth originating from employing a porous dielectric film, while reducing interconnect capacitance by introduction of the porous dielectric film.

According to the present invention, there is provided a semiconductor device comprising a semiconductor substrate; and a dielectric film consisting essentially of a porous film and a non-porous film in contact therewith formed on the semiconductor substrate; and the porous film and the non-porous film are substantially of an identical composition.

In this semiconductor device, since a compound constituting the porous film and that constituting the non-porous film have a substantially identical composition, affinity of the porous film and the non-porous film is upgraded and excellent adhesion is achieved. As a result, the conventionally observed problem of insufficient adhesion between a porous film and an adjacent film is eliminated and a highly reliable semiconductor device is obtained. The above compounds are generally polymers, and it is preferable that they have a same basic structure though they may have a different degree of polymerization. It is preferable that both of the porous film and the non-porous film are organic films constituted of an organic compound, particularly an organic silicon compound. Employing such materials stably upgrades the affinity of these films, resulting in improved adhesion between the films.

According to the present invention, there is provided a semiconductor device comprising a semiconductor substrate; and a dielectric film consisting essentially of a porous film and a non-porous film adjacent thereto formed on the semiconductor substrate; and the porous film and the non-porous film both contain Si, O and C.

In this semiconductor device, since both of the porous film and the non-porous film contain Si, O and C, affinity of the films is upgraded and excellent adhesion is achieved. Materials constituting the respective films may be either identical or different, and in either case as long as a basic structure is the same the affinity of the films is further upgraded and a significant improvement of adhesion is accomplished. Examples of films containing Si, O and C include a coated film such as MSQ (methylsilsesquioxane) or MHSQ (methylhydrosilsesquioxane) and a CVD-formed film such as an SiOC film.

In the first and the second semiconductor devices, the non-porous film may be disposed either on or under the porous film. When forming the non-porous film on the porous film the former serves as a protection layer for the latter, for effectively preventing the porous film from being damaged during a treatment such as CMP or a deposition process.

Further, in these semiconductor devices, it is preferable to constitute the porous film and the non-porous film such that a difference in dielectric constant becomes not greater than 1. As a result, increase of dielectric constant of the porous film can be restrained even when a material of the non-porous film has penetrated into a pore of the porous film.

According to the present invention, there is provided a semiconductor device comprising a semiconductor substrate; and a dielectric film having a substantially uniform composition including a porous portion; and pores in the porous portion are distributed in a relatively lower density at least either in the proximity of an upper surface or in the proximity of a lower surface of the dielectric film. In other words, density of the pores in the proximity of the upper and/or lower surface of the dielectric film is lower than that of the pores in an interior portion of the dielectric film. Such dielectric film has a low dielectric constant as the pores are included in its interior portion, while provides an excellent adhesion with an adjacent film since the pores in the proximity of its upper surface and/or its lower surface are distributed in a relatively lower density. Consequently, reliability of the semiconductor device can be significantly upgraded.

In this semiconductor device, it is also possible to form a non-porous structure in the portion close to the upper surface and/or the lower surface of the dielectric film. As a result, adhesion with an adjacent film is further enhanced. Also, increase of dielectric constant of the dielectric film due to penetration of a material of the film adjacent to the dielectric film can be effectively restrained.

The pores in the dielectric film can be distributed in a desired density. For example, in case where the pores are less densely distributed in an upper portion of the dielectric film farther from the semiconductor substrate, the upper portion of the dielectric film can serve as a protection layer and the dielectric film can have both a low dielectric constant and a stable structure. In addition, by making the distribution of the pores such that the pores are more densely distributed in the middle portion of the dielectric film farther from the semiconductor substrate and the pores are less densely distributed in the upper portion of the dielectric film, the adhesion with an adjacent films and the upper and lower surface of the dielectric film are further enhanced while the dielectric constant of the dielectric film is being kept low.

In the foregoing semiconductor devices, it is also possible to provide a metal interconnect in the dielectric film, such that an upper surface of the metal interconnect and that of the dielectric film are aligned in a same plain. In this case, a certain load is imposed on the upper surface of the dielectric film during a formation process of the metal interconnect. For example, when forming the metal interconnect by CMP process, the dielectric film is inevitably polished together with a metal film constituting the metal interconnect. For such reason an enhanced mechanical strength of the dielectric film surface is required, whereas the surface of the dielectric film according to the invention has a lower pore density, and therefore has significantly higher resistance against the CMP process than an ordinary porous film.

In the above semiconductor devices the dielectric film can be formed by CVD. As a result of forming both the porous portion and the non-porous portion of the dielectric film by CVD, adhesion between the portions can be further assured. Also the entire multiple layers can be formed through an integrated process without being taken out of a deposition chamber, therefore stability in quality is also upgraded.

According to the present invention, there is provided a method of manufacturing a semiconductor device comprising forming a dielectric layer on a semiconductor substrate by forming a porous film and forming thereon a non-porous film having a substantially same composition as the porous film; selectively removing a portion of the dielectric film to form a recess; forming a metal layer so as to fill the recess; and performing either polishing or etch-back of the metal layer to an extent that the porous film is not exposed, to remove the metal layer formed outside the recess.

According to this manufacturing method, since the porous film and the non-porous film have a substantially identical composition, affinity of the porous film and the non-porous film is upgraded and excellent adhesion is achieved. Also, since polishing or etch-back is performed on the metal layer without exposing the porous film, the metal layer can be formed in the recess without damaging the dielectric film quality.

According to the present invention, there is provided a method of manufacturing a semiconductor device comprising the forming a dielectric layer on a semiconductor substrate by forming a porous film containing Si, O and C and forming thereon a non-porous film containing Si, O and C; selectively removing a portion of the dielectric film to form a recess; forming a metal layer so as to fill the recess; and performing either polishing or etch-back of the metal layer to an extent that the porous film is not exposed, to remove the metal layer formed outside the recess.

According to this method of manufacturing a semiconductor device, since both of the porous film and the non-porous film contain Si, O and C, affinity of the films is upgraded and excellent adhesion is achieved. Also, since polishing or etch-back is performed on the metal layer without exposing the porous film, the metal layer can be formed in the recess without damaging the dielectric film quality.

According to the present invention, there is provided a method of manufacturing a semiconductor device comprising forming a porous-structured dielectric film having a substantially uniform composition on a semiconductor substrate; and the forming the dielectric film includes controlling a deposition condition to vary a density of pores.

This manufacturing method permits optionally controlling the pore density in the dielectric film, and such dielectric film having the pores distributed in a relatively lower density in the proximity of its upper surface or its lower surface can be easily achieved. In case where the formation condition is controlled such that the pores are less densely distributed in the proximity of the upper surface of the dielectric film, the upper surface of the dielectric film can serve as a protection layer during a treatment process of the upper portion of the dielectric film, resulting in upgraded reliability of the semiconductor device.

Various methods are feasible to form the porous-structured dielectric film. For example, in case of adopting a vapor phase growth process such as CVD, a film deposition condition such as a deposition gas type can be adjusted half way such that the pore density can be varied. Employing a deposition gas that encourages formation of a porous structure in the former half of the deposition process and a deposition gas that restrains formation of pores in the latter half results in formation of a dielectric film having varying pore density therein.

Another effective method is to introduce a template in the deposition process of the dielectric film, in accordance with time, varying the introduction quantity of the template during the deposition process. Upon decomposing or removing the template after deposition of the dielectric film, a porous-structured dielectric film is obtained. In this case, a spin coating process can also be employed as a deposition method, in addition to the vapor phase growth including the CVD.

According to the present invention, there is provided a method of manufacturing a semiconductor device comprising forming a dielectric film on a semiconductor substrate by forming a first film containing a template and forming a second film not containing a template in this sequence; selectively removing a portion of the dielectric film to form a recess; and performing heat treatment on the first film to decompose or remove the template, thereby forming a porous structure in the dielectric film.

According to this manufacturing method, the first film and the second film are consecutively deposited and then the first film is processed to obtain a porous structure. As a result, a dielectric film having a low dielectric constant and excellent adhesiveness can be obtained through a simple process and at a stable quality level.

This method of manufacturing a semiconductor device may further comprise the forming a metal layer so as to fill the recess; and performing either polishing or etch-back of the metal layer until a surface of the dielectric film is exposed, to remove the metal layer formed outside the recess. As a result, since polishing or etch-back is performed on the metal layer without exposing the porous portion inside the dielectric film, the metal layer can be formed in the recess without damaging the dielectric film quality. Here, the “recess” referred to in all the foregoing methods of manufacturing a semiconductor device according to the invention specifically represents an interconnect trench, a contact hole, a recess for disposing a pad and so forth.

In the foregoing methods of manufacturing a semiconductor device according to the invention, the forming the dielectric film may include forming the dielectric film in an integrated process without taking the substrate out of a CVD deposition chamber, and employing a deposition gas containing a template during a process of forming a porous portion of the dielectric film and employing a deposition gas not substantially containing a template during a process of forming a non-porous portion. As a result, a dielectric film having both a porous portion and a non-porous portion can be obtained at a high and stable quality level.

The “porous” structure referred to in the invention stands for a porous structure intentionally formed through employment of a template or selection of a deposition gas. From the viewpoint of reduction of dielectric constant, it is preferable that an average pore diameter becomes not less than 1 nm. The average diameter can be obtained by, for example, observing a cross section of a film through an electron microscope.

As described above, the invention provides a solution of the problem of insufficient adhesion, degradation of mechanical characteristics of a dielectric film and complication of manufacturing process of the same and so forth originating from employing a porous dielectric film, while successfully reducing interconnect capacitance by introduction of the porous dielectric film.

### BRIEF DESCRIPTION OF THE DRAWINGS

FIG. 1 is a schematic cross-sectional view showing a conventional semiconductor device;

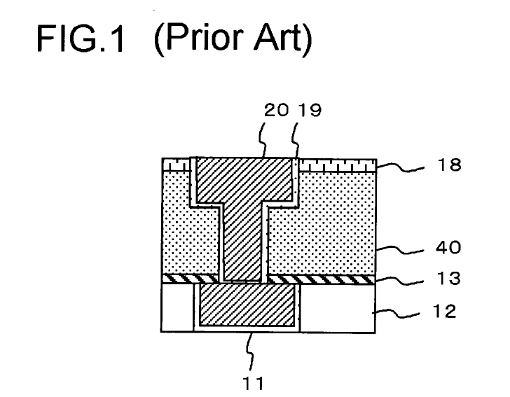

FIGS. 2A and 2B are schematic cross-sectional views respectively showing a semiconductor device according to the present invention;

FIGS. 3A to 3C are schematic cross-sectional views respectively showing a semiconductor device according to the invention;

FIGS. 4A and 4B are schematic cross-sectional views progressively showing a manufacturing method of a semiconductor device according to the invention;

FIGS. 5A to 5C are schematic cross-sectional views progressively showing a manufacturing method of a semiconductor device according to the invention;

FIGS. 6A and 6B are schematic cross-sectional views progressively showing a manufacturing method of a semiconductor device according to the invention;

FIGS. 7A to 7C are schematic cross-sectional views progressively showing a manufacturing method of a semiconductor device according to the invention;

FIGS. 8A and 8B are schematic cross-sectional views progressively showing a manufacturing method of a semiconductor device according to the invention; and

FIG. 9 is a schematic cross-sectional view showing a semiconductor device according to the invention.

### DETAILED DESCRIPTION OF THE INVENTION

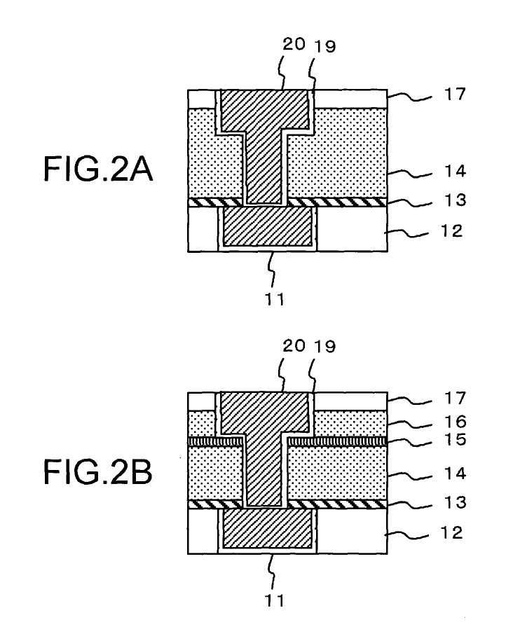

FIGS. 2A and 2B are respectively showing an interconnect structure according to the present invention. This interconnect structure is provided with an interlayer dielectric film formed by spin-on coating and a copper interconnect line formed by dual damascene process.

The interconnect structure of FIG. 2A is constituted of multi-layers including an interconnect dielectric film 12, a copper diffusion barrier 13, a porous MSQ film 14 and a non-porous MSQ film 17 formed on a silicon substrate (not shown). A lower interconnect 11 is disposed in the interconnect dielectric film 12, and an upper interconnect consisting of a copper layer 20 and a barrier metal 19 and a via plug are provided through a dielectric film consisting of the copper diffusion barrier 13, the porous MSQ film 14 and the non-porous MSQ film 17. The lower interconnect 11 and the upper interconnect are connected through a via hole.

The porous MSQ film 14 is a dielectric film having a porous structure. Specifically, the porous MSQ film 14 can be constituted of a porous-structured coated film having a siloxane base such as MSQ, MHSQ or HSQ, or a porous-structured CVD film such as an SiOC film. Here, the SiOC layer normally consists essentially of elements of Si, O, C and H, and may therefore be referred to as “SiOCH layer”. A porous-structured coated film can be formed through the steps of spin-coating a solution containing a precursor for constitution of the dielectric film and a template on a substrate, and then performing heat treatment to achieve a porous structure. By contrast, a porous-structured CVD film can be formed through an appropriate selection of a deposition condition such as a type of deposition gas.

The non-porous MSQ film 17 is a dielectric film having a non-porous structure. This dielectric film serves as a protection layer for the porous MSQ film 14. In a formation process of the copper layer 20 by dual damascene process, a load is imposed on an upper surface of the dielectric film aligned in a same plain with an upper surface of the copper layer 20. However since the portion on which a load is imposed is the non-porous MSQ film 17 and not the porous MSQ film 14 in the structure of FIG. 2A, resistance against CMP process is significantly upgraded.

The non-porous MSQ film 17 also serves as an adhesive film interleaved between the porous MSQ film 14 and an upper adjacent film for upgrading the adhesion of the interlayer dielectric film. It is preferable that the porous MSQ film 14 and the non-porous MSQ film 17 contain an organic silicon compound of a same composition as their constituent, more preferably as their main constituent. As a result, adhesion between these films is further enhanced. It is also preferable that the porous MSQ film 14 and the non-porous MSQ film 17 both contain a compound including Si, O and C, for example polyorganosiloxane. The polyorganosiloxane contained in the respective films may be either identical or different, and in either case as long as a basic structure is the same the affinity of the films is further upgraded and a significant improvement of adhesion is accomplished.

In addition, the non-porous MSQ film 17 can be constituted of a coated film having a siloxane base such as MSQ, MHSQ or HSQ, or a CVD film such as an SiOC film.

FIG. 2B shows another interconnect structure provided with an interlayer dielectric film formed by coating. A structural difference from FIG. 2A is that an etching barrier 15 is disposed so as to contact with a lower face of the barrier metal 19, and that a porous MSQ film 16 is provided on the etching barrier 15. The remaining portion is the same as FIG. 2A.

The etching barrier 15 serves to block an excessive etching effect during formation of an interconnect trench for the copper layer 20. The etching barrier 15 maybe constituted of SiN, SiON, SiC, SiCN or SiO₂ and the like.

In the configurations shown in FIGS. 2A and 2B, a protection layer constituted of SiC, SiCN, SiO₂, etc. may be provided on the non-porous MSQ film 17. As a result, resistance against a CMP process for formation of the copper layer 20 is further upgraded.

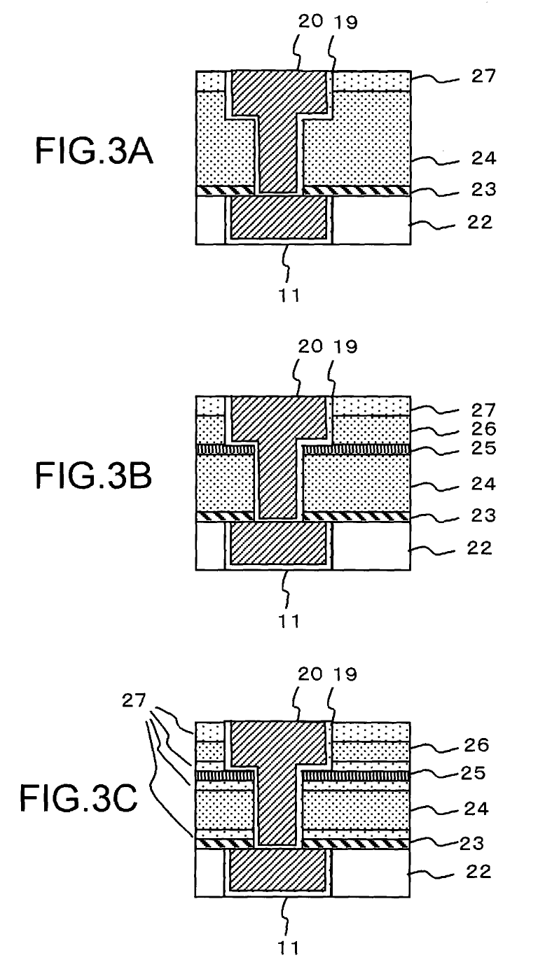

FIGS. 3A to 3C are respectively showing another interconnect structure according to the invention. This interconnect structure is provided with an interlayer dielectric film formed by CVD process and a copper interconnect line formed by dual damascene process.

FIG. 3A shows a similar layer structure to that of FIG. 2A, except that the interlayer dielectric film is constituted of a CVD film instead of a coated film. The interconnect structure of FIG. 3A is constituted of multi-layers including an interconnect dielectric film 22, a copper diffusion barrier 23, a porous SiOC film 24 and a non-porous SiOC film 27 formed on a silicon substrate (not shown). A lower interconnect 11 is disposed in the interconnect dielectric film 22, and an upper interconnect consisting of a copper layer 20 and a barrier metal 19 and a via plug are provided through the multiple layers formed on the interconnect dielectric film 22. The lower interconnect 11 and the upper interconnect are connected through a via hole. Since both of the porous SiOC film 24 and the non-porous SiOC film 27 are formed by CVD, a deposition condition such as a type of deposition gas can be changed halfway without suspending the process. As a result, adhesion between the films is further upgraded. Also, through an appropriate selection of a deposition condition, it is possible to create a gradual variation of pore density from the porous SiOC film 24 toward the non-porous SiOC film 27.

FIG. 3B shows a similar layer structure to that of FIG. 3A, except that an etching barrier 25 is disposed so as to contact with a lower face of the barrier metal 19, and that a porous SiOC film 26 is provided on the etching barrier 25. The remaining portion is the same as FIG. 3A.

In a structure shown in FIG. 3C, the non-porous SiOC film 27 is disposed on an upper surface of the copper diffusion barrier 23, an upper surface and lower surface of the etching barrier 25 respectively. Therefore adhesion between the porous film and an adjacent film is prominently upgraded. Referring to a porous structure of a CVD film, distribution of pores in the film can be controlled through a relatively simple operation when changing a deposition gas. The structure as FIG. 3C can be easily obtained by employing such controlling technique of pore distribution. Meanwhile, when changing a deposition gas, either mode can be adopted whether to purge the existing atmosphere once out of a deposition chamber before introducing a new deposition gas, or to just introduce a new deposition gas without purging the existing atmosphere. In the former case, a boundary of the film nature is evidently marked, therefore the film composition can be easily controlled. In the latter case, pore density gradually changes in a region between a portion of a high pore density and that of a low pore density, because of a memory effect of the deposition gas used in the former process. In this way, a greater mechanical strength of the film can be achieved than in the case where the boundary is evidently marked. In another embodiment, referring to FIG. 3C a part of the plurality of layers of non-porous SiOC film 27 may be omitted.

Now referring to the accompanying drawings, some embodiments of manufacturing method of a semiconductor device according to the invention will be described in the followings. The porous structure referred to in the following embodiments stands for a structure intentionally formed through employment of a template or selection of a deposition gas, such that an average pore diameter becomes not less than 1 nm.

### FIRST EMBODIMENT

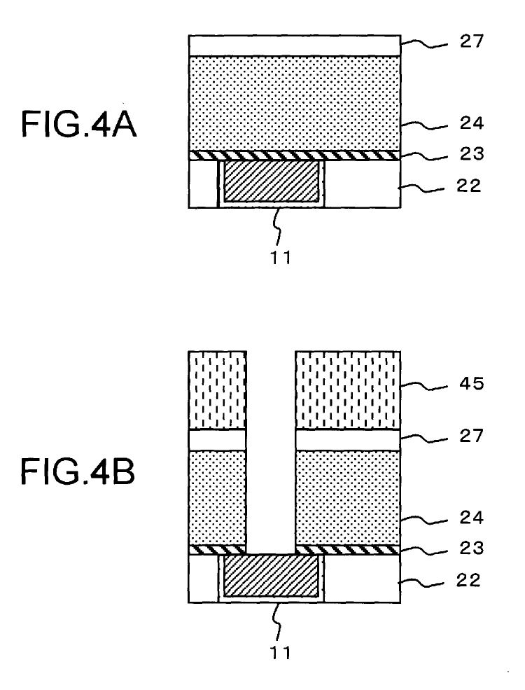

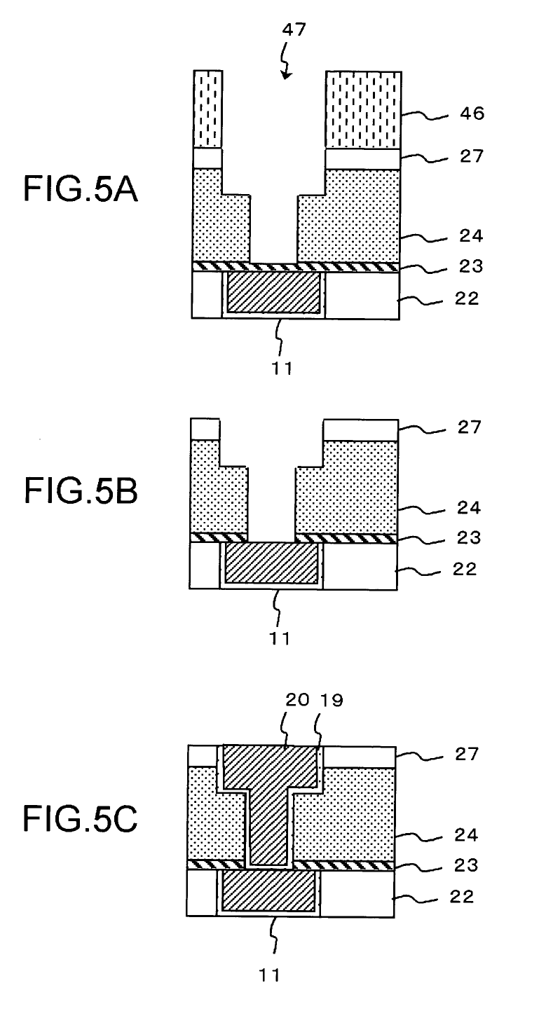

FIGS. 4A through 5C are schematic cross-sectional views progressively showing a manufacturing method of the interconnect structure shown in FIG. 2A. In this embodiment, an interconnect structure provided with multiple layers of copper interconnect line is to be formed by dual damascene process. As an interlayer dielectric film, a CVD-processed SiOC film is employed.

Firstly the following steps 1 through 4 are performed, to obtain a structure shown in FIG. 4A.

### Step 1

A lower interconnect 11 consisting of a copper layer and a barrier metal, and an interconnect dielectric film 22 are formed on a silicon substrate (not shown), and a copper diffusion barrier 23 (thickness: 50 nm) is formed over the lower interconnect 11 and the interconnect dielectric film 22 by plasma CVD process. The copper diffusion barrier 23 may be constituted of, for example, SiN, SiON, SiC or SiCN, among which SiN is employed in this embodiment. As a source gas for the SiN film, for example a gas mixture containing monosilane and ammonium or a gas mixture containing dichrolosilane and ammonium can be employed. Deposition temperature is set in a range of 300° C. to 600° C. In case where SiCN is used as the copper diffusion barrier 23, for example trimethylsilane and ammonium may be used as the source gas, under a deposition temperature ranging, for example, from 300° C. to 600° C.

### Step 2

A porous SiOC film (k=2.0 to 2.5) is deposited on the copper diffusion barrier 23 by plasma CVD. The film thickness may be in a range of, for example, 400 to 700 nm. A gas mixture containing the following components A, B and C can be employed as a deposition gas.

(A) Organosilane or organosiloxane

(B) Oxidizer such as N₂O, O₂, O₃, CO₂

(C) Template

The porous SiOC film 24 can be formed to have a desired amount of pores by employing such gas mixture and appropriately controlling a deposition condition. Pore density can be adjusted through appropriate selection of a type of the organosilane. The deposition temperature is to be selected in a range of 300° C. to 500° C.

As an example of the component A, an organosilane designated by RnSiH₄-n (R stands for an alkyl base, and n is an integer of 1 to 4) can be employed.

As a template example of the component C, a cycloalkene containing a silicon based unit and a thermally unstable non-silicon based unit can be employed.

Examples of the silicon-based unit include a methylsiloxy (CH₃—SiH₂—O—) unit, dimethylsiloxy (CH₃)₂—SiH—O—) unit, and the like.

Examples of non-silicon based unit having a thermally unstable base include dioxynil- (—CH═CH—O—CH═CH—O—)—), furanyl (—(—CH═CH—CH═CH—O—)—), fulvenyl (—(—CH═CH—CH═CH—C(CH₂)—)—), etc., and a fluorine substitution of these.

Specific examples of the cycloalkene having such unit include:

methylsilyl-1,4-dioxynilether;

2-methylsiloxanilfuran;

3-methylsiloxanilfuran;

2,5-bis(methylsiloxy)-1,4-dioxyn;

3,4-bis(methylsiloxanil)furan;

2,3-bis(methylsiloxanil)furan;

2,4-bis(methylsiloxanil)furan;

2,5-bis(methylsiloxanil)furan;

1-methylsiloxanilfulvene;

2-methylsiloxanilfulvene;

6-methylsiloxanilfulvene;

bis(methylsiloxanil)fulvene;

dimethylsilyl-1,4-dioxynilether;

2-dimethylsiloxanilfuran;

3-dimethylsiloxanilfuran;

2,5-bis(dimethylsiloxy)-1,4-dioxyn;

3,4-bis(dimethylsiloxanil)furan;

2,3-bis(dimethylsiloxanil)furan;

2,4-bis(dimethylsiloxanil)furan;

2,5-bis(dimethylsiloxanil)furan;

1-dimethylsiloxanilfulvene;

2-dimethylsiloxanilfulvene;

6-dimethylsiloxanilfulvene;

bis (dimethylsiloxanil)fulvene;

2,4,6-trisilaoxane; and

cyclo-1,3,5,7-tetrasilylene-2,6-dioxy-4,8-dimethylene;

and a fluorine substitution of these, out of which one or a combination of two or more can be employed.

### Step 3

The substrate on which the porous SiOC film 24 has been formed is taken out of a deposition chamber, and furnace-anneal is performed. This turns the porous SiOC film 24 into a stabilized film. Annealing temperature may be set higher than that of the deposition temperature, that is for example, in a range of 300° C. to 500° C.

A non-porous SiOC film 27 (thickness: 50 to 350 nm, k=2.9) is formed on the porous SiOC film 24. The thickness of the non-porous SiOC film 27 is preferably set in accordance with the thickness of the porous SiOC film 24. It is preferable to form the non-porous SiOC film 27 in a similar manner to the porous SiOC film, and accordingly the plasma CVD is employed in this embodiment. For the deposition of the non-porous SiOC film 27 the same gas can be used as that used for the porous SiOC film 24 except the template, while a different deposition gas from the gas which was used for the porous SiOC film 24 may also be employed.

Upon completing the foregoing steps, the structure as shown in FIG. 4A is obtained. Successively the following steps 5 to 8 will be performed.

### Step 5

A resist pattern 45 is formed by an ordinary exposure, and anisotropic etching is performed on the non-porous SiOC film 27 and the porous SiOC film 24 to form a via hole. Then the resist pattern 45 is removed by oxygen plasma treatment (FIG. 4B).

### Step 6

A resist pattern 46 is formed by an ordinary exposure, and anisotropic etching is performed on the non-porous SiOC film 27 and the porous SiOC film 24 to form an interconnect trench 47 (FIG. 5A). Then the resist pattern 46 is removed.

### Step 7

Etch-back is performed on the copper diffusion barrier 23, so that the via hole reaches the lower interconnect 11. By this etch-back process the copper diffusion barrier 23 is removed by approx. 50 nm and also the non-porous SiOC film 27 is removed by approx. 70 nm (FIG. 5B). Also, an etching selectivity of the non-porous SiOC film 27 with respect to the copper diffusion barrier 23 can be controlled by altering an etch-back condition.

### Step 8

A barrier metal 19 (thickness: 50 nm) is formed all over the interconnect trench and the via hole formed as above, after which a copper layer 20 (thickness: 700 nm) is deposited. In this embodiment Ta is employed as the barrier metal 19, while it is also possible to employ one or a combination of Ti, TiN, TaN, TiW, TaW, WN, and the like. For deposition of the barrier metal 19, normally CVD is employed while sputtering can also be utilized. For deposition of the copper layer 20, plating is employed in this embodiment while CVD or sputtering can also be utilized.

Then the barrier metal 19 and the copper layer 20 are polished by CMP process, to form a via plug and an upper interconnect. Polishing is to be finished when a surface of the non-porous SiOC film 27 is exposed. Upon completing these steps, the interconnect structure shown in FIG. 5C is obtained.

In this interconnect structure, since a substantial part of the interlayer dielectric film is constituted of the porous SiOC film 24 having a low dielectric constant, a parasitic capacitance between interconnect lines can be effectively reduced. Also, since the non-porous SiOC film 27 is formed over the porous SiOC film 24, the porous SiOC film 24 can be kept from being damaged in the CMP process of FIG. 5C. Further, since the non-porous SiOC film 27 and the porous SiOC film 24 are constituted of a compound having the same composition, excellent adhesion is achieved at an interface between these films. In addition, the non-porous SiOC film 27 is sufficiently adhesive to additional layers such as another copper diffusion barrier to be formed over this interconnect structure.

### SECOND EMBODIMENT

In this embodiment, the following step 2′ is to be performed in place of the steps 2 to 4 of the first embodiment.

### Step 2′

The porous SiOC film 24 (thickness: 400 to 700 nm) and the non-porous SiOC film 27 (thickness: 50 to 350 nm) are formed by plasma CVD on the copper diffusion barrier 13. The deposition gases for the respective films are the same as those used in the first embodiment, however in this embodiment the deposition gas is changed while consecutively forming these films, without taking the substrate out of the deposition chamber. This can be performed for example in the following method.

A gas mixture containing the following components A, B and C can be employed as a deposition gas.

(A) Organosilane or organosiloxane

(B) Oxidizer such as N₂O, O₂, O₃, CO₂

(C) Template

For the deposition of the porous SiOC film 24 and the non-porous SiOC film 27, the components A and B are supplied. For depositing the porous SiOC film 24, the template of C is additionally introduced. At a transition stage to the deposition of the non-porous SiOC film 27, supply of the template is stopped.

Here, when changing the deposition gas, either mode is feasible whether to purge the existing atmosphere once out of the deposition chamber before introducing the new deposition gas, or to gradually change the composition of the deposition gas without purging the existing atmosphere. By the latter mode, the film obtains a graded structure in which pore density is gradually varying.

Then the steps 5 and 6 according to the first embodiment are performed, and thereafter the following step 6′ is performed.

### Step 6′

Upon removing the resist pattern from the structure of FIG. 4B, the substrate is introduced into a furnace to perform the furnace-anneal. In this process, a low-molecular compound and so forth remaining in the porous SiOC film 24 are volatilized through the via hole. As a result the porous SiOC film 24 gains stable film characteristics. Annealing temperature may be set higher than that of the deposition temperature, that is for example in a range of 300° C. to 550° C.

According to this embodiment, since the porous SiOC film 24 and the non-porous SiOC film 27 are consecutively formed, a number of manufacturing processes can be reduced, and the dielectric film gains an enhanced mechanical strength.

In case where a new deposition gas is introduced after purging a former gas in the step 2′, an evidently divided layered structure constituted of the the porous SiOC film 24 and the non-porous SiOC film 27 is formed as shown in FIGS. 4A through 5C. By contrast, in case where the deposition gas is changed without purging the former gas, the boundary of these films is not clearly marked and pore density in the dielectric film gradually becomes lower toward an upper portion farther from the substrate.

A dielectric film in which the pore density gradually becomes lower toward an upper portion farther from the substrate can also be obtained by progressively changing the deposition gases. By such method, a dielectric film having both a low dielectric constant and excellent interlayer adhesion can be stably manufactured.

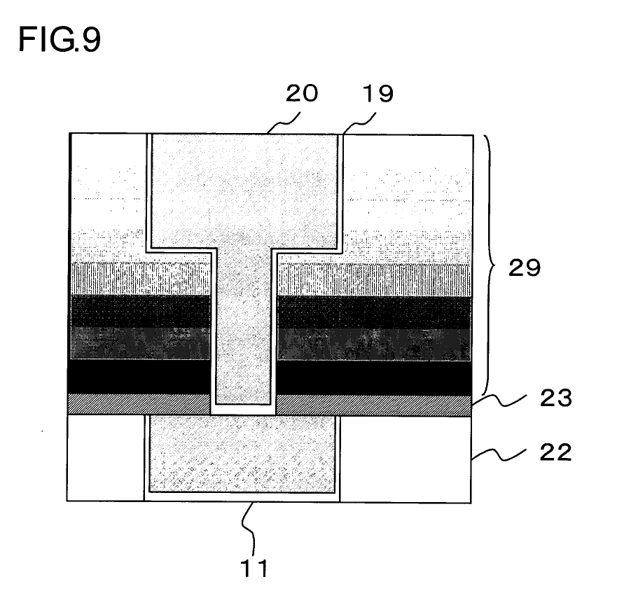

This embodiment has presented a method of forming a porous and a non-porous structure by providing the template or not, while it is also possible to adjust the pore density by changing the introduction amount of the template. By such method, a structure in which the pores are relatively less densely distributed in the proximity of an upper surface or a lower surface of the dielectric film can be easily formed. FIG. 9 shows an example of such structure. Referring to FIG. 9, a dielectric film 29 has a graded structure in which the pore density gradually becomes lower toward an upper portion farther from the substrate. An upper surface of the dielectric film 29 is aligned at the same level as the interconnect, where the dielectric film 29 is non-porous. As a result of forming such structure, the adhesion between the dielectric film and an adjacent film is upgraded. Also, damage to the dielectric film can be minimized though a mechanical treatment such as CMP is applied after forming the dielectric film.

### THIRD EMBODIMENT

In this embodiment, an interconnect structure provided with multiple layers of copper interconnect line is to be formed by dual damascene process. As an interlayer dielectric film, an MSQ film formed by spin-on coating is employed.

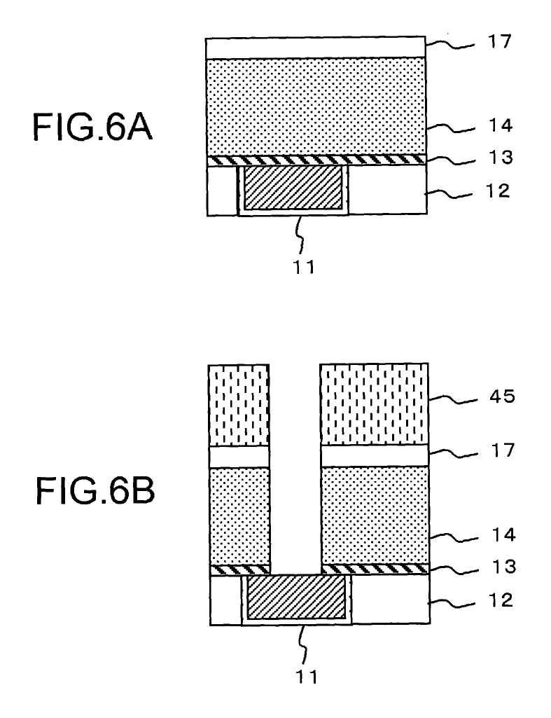

Firstly the following steps 1 through 4 are performed, to obtain a structure shown in FIG. 6A.

### Step 1

A copper diffusion barrier 13 (thickness: 50 nm) is formed over the lower interconnect 11 constituted of copper and an interconnect dielectric film 12 by plasma CVD process. The copper diffusion barrier 13 may be constituted of, for example, SiN, SiON, or SiC, among which SiN is employed in this embodiment. As a source gas for the SiN film, for example a gas mixture containing monosilane and ammonium or a gas mixture containing dichrolosilane and ammonium can be employed. Deposition temperature is set in a range of 300° C. to 600° C. In case where SiC is used as the copper diffusion barrier 13, for example trimethylsilane and ammonium may be used as the source gas, under a deposition temperature ranging, for example, from 300° C. to 450° C.

### Step 2

An MSQ film is formed on the copper diffusion barrier 13 by spin-on coating, utilizing a film material containing a silica-based precursor and a template. The film thickness is suitably determined depending on a relation with a thickness of a non-porous MSQ film to be subsequently formed, preferably in a range of 400 to 700 nm.

As the silica-based precursor an organic silicon compound containing SiOC or SiOCH such as organosiloxane, organosilane, siloxane can be employed.

Examples of a material of the template include a metal chelate compound containing a metal atom such as phospher, titanium, zirconium and aluminum, a surface-active agent, or inorganic compound nano-particles such as GeO₂.

### Step 3

Heat treatment is performed to remove the template and to thereby achieve a porous structure. At this stage, the MSQ film turns into a porous MSQ film 14. Here, it is preferable to set the heat treatment temperature higher than the deposition temperature, for example in a range of 200° C. to 450° C.

### Step 4

A non-porous MSQ film 17 (thickness: 50 to 350 nm) is formed on the porous MSQ film 14 by spin-on coating, utilizing a film material containing a silica-based precursor but not a template. The thickness of the non-porous SiOC film 17 is preferably set in accordance with the thickness of the porous SiOC film 14. Either the identical silica-based precursor to that used for formation of the porous MSQ film 14 or a different one can be employed.

Upon completing the foregoing steps, the structure of FIG. 6A is obtained. Successively the following steps 5 to 8 will be performed, in a similar manner to the first embodiment.

### Step 5

A resist pattern 45 is formed, and anisotropic etching is performed to open a via hole. Then the resist pattern 45 is removed by oxygen plasma treatment (FIG. 6B).

### Step 6

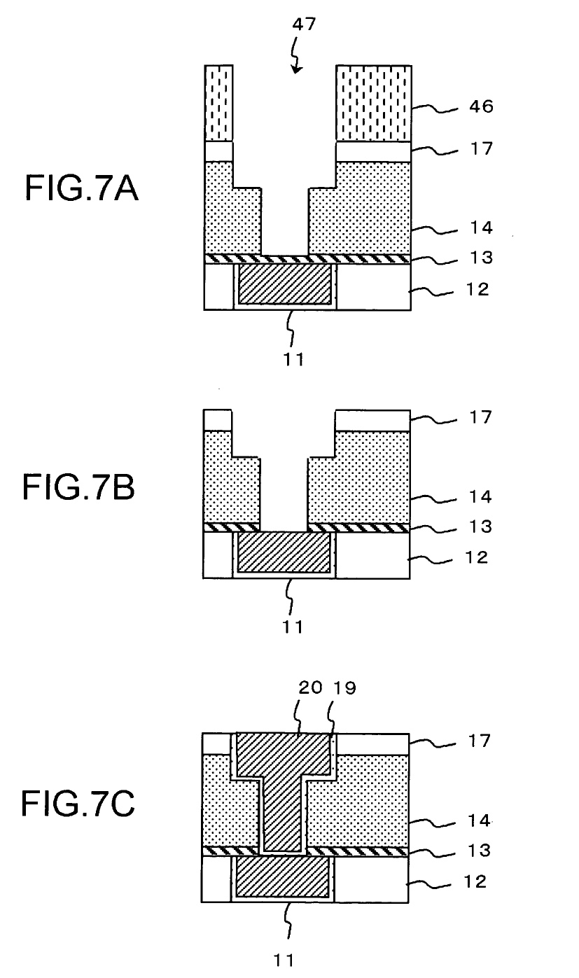

A resist pattern 46 is formed, and anisotropic etching is performed to form an interconnect trench 47 for disposing therein a damascene interconnect line (FIG. 7A).

### Step 7

After removing the resist pattern 46, etch-back is performed on the copper diffusion barrier 13, so that the via hole reaches the lower interconnect 11 (FIG. 7B).

### Step 8

A barrier metal 19 (thickness: 50 nm) is formed all over the interconnect trench and the via hole formed as above, after which a copper layer 20 (thickness: 700 nm) is deposited. Then the barrier metal 19 and the copper layer 20 are polished by CMP process, to form a via plug and an upper interconnect. Polishing is to be finished when a surface of the non-porous MSQ film 17 is exposed. Upon completing these steps, the interconnect structure shown in FIG. 7C is obtained.

In this interconnect structure, since a substantial part of the interlayer dielectric film is constituted of the porous film having a low dielectric constant, a parasitic capacitance between interconnect lines can be effectively reduced. Also, this interconnect structure has excellent resistance against CMP and interlayer adhesion.

### FOURTH EMBODIMENT

In this embodiment, an MSQ film formed by spin-on coating is employed as an interlayer dielectric film, to form an interconnect structure in a similar manner to the third embodiment. According to this embodiment, formation process of the interlayer dielectric film is simplified, so that a number of manufacturing processes is reduced.

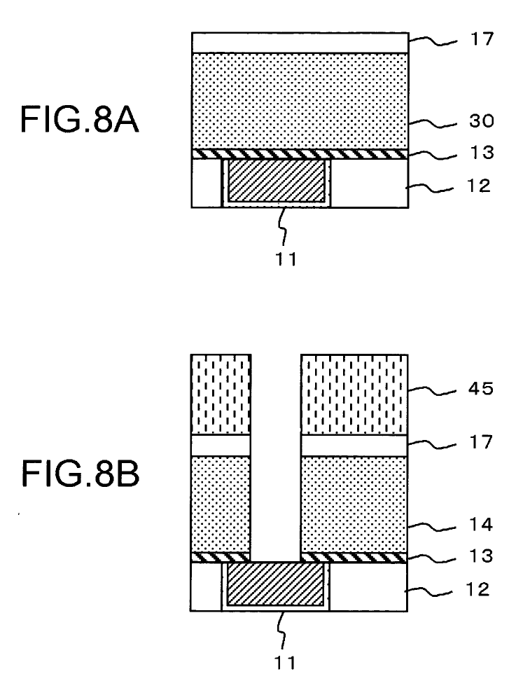

In this embodiment, the same steps 1 and 2 as those of the third embodiment are performed, but the step 3 of performing the heat treatment to form a porous structure is omitted. Then the step 4 is performed to obtain a structure of FIG. 8A. In FIG. 8A, an MSQ film 30 containing a template is formed on the copper diffusion barrier 13.

Then the step 5 is performed, in which a via hole is formed by anisotropic etching. After removing the resist pattern 45 by oxygen plasma treatment, heat treatment is performed, in this embodiment on the substrate, to remove the template and to thereby giving a porous structure to the MSQ film 30. At this stage, the MSQ film 30 turns into a porous MSQ film 14 (FIG. 8B). Here, it is preferable to set the heat treatment temperature higher than the deposition temperature, for example in a range of 200° C. to 450° C.

Thereafter, the steps 6 and the following steps are performed in a similar manner to the third embodiment, to form the interconnect structure.

According to this embodiment, since the MSQ film is consecutively formed a number of manufacturing process can be reduced.

As above, the invention has been described referring to the foregoing embodiments. It is to be understood that these embodiments are only exemplifying and that it is apparent to those skilled in the art that various modifications can be made to the respective constituents or processing steps or combinations thereof, without departing from the spirit and scope of the invention. For example, the foregoing embodiments are described with respect to an interconnect structure to be formed by dual damascene process, however the invention can equally be applied to a formation process of an interconnect or a plug according to single damascene process.

Also, selection of a material for the dielectric film, interconnect, barrier metal etc. is not limited to the above description, but can be made in a different manner. For example in the third and fourth embodiments, a film constituted of a mixture of MSQ and MHSQ can also be employed instead of the MSQ film. Further, the location of the boundary of the porous film and the non-porous film is not limited to the examples shown in the drawings but can be optionally disposed at a different level, thus to adjust a film thickness ratio of these films according to a design.

What is claimed is:

1. A semiconductor device comprising:
a semiconductor substrate; and
a dielectric film including a porous film and a non-porous film in contact therewith formed on said semiconductor substrate;
wherein said porous film and said non-porous film are substantially of an identical composition.

2. The semiconductor device as set forth in claim 1, wherein said non-porous film is disposed on top of said porous film.

3. The semiconductor device as set forth in claim 1, wherein said dielectric film is formed by CVD.

4. The semiconductor device as set forth in claim 1, wherein an average diameter of pores contained in the porous portion is not less than 1 nm.

5. The semiconductor device as set forth in claim 1, wherein said pores are distributed in a relatively lower density in the proximity of an upper surface of said dielectric film.

6. The semiconductor device as set forth in claim 1, wherein a metal interconnect is provided in said dielectric film, such that an upper surface of said metal interconnect and that of said dielectric film are aligned in a same plain.

7. A semiconductor device comprising:
a semiconductor substrate; and
a dielectric film including a porous film and a non-porous film in contact therewith formed on said semiconductor substrate;
wherein said porous film and said non-porous film both contain Si, O and C.

8. The semiconductor device as set forth in claim 7, wherein said non-porous film is disposed on top of said porous film.

9. The semiconductor device as set forth in claim 7, wherein said dielectric film is formed by CVD.

10. The semiconductor device as set forth in claim 7, wherein an average diameter of pores contained in the porous portion is not less than 1 nm.

11. The semiconductor device as set forth in claim 7, wherein said pores are distributed in a relatively lower density in the proximity of an upper surface of said dielectric film.

12. The semiconductor device as set forth in claim 7, wherein a metal interconnect is provided in said dielectric film, such that an upper surface of said metal interconnect and that of said dielectric film are aligned in a same plain.

13. A semiconductor device comprising:
a semiconductor substrate; and
a dielectric film having a substantially uniform composition including a porous portion;
wherein pores in said porous portion are distributed in a relatively lower density either in the proximity of an upper surface or in the proximity of a lower surface of said dielectric film.

14. The semiconductor device as set forth in claim 13, wherein said pores are distributed in a relatively lower density in the proximity of an upper surface of said dielectric film.

15. The semiconductor device as set forth in any of claim 13, wherein a metal interconnect is provided in said dielectric film, such that an upper surface of said metal interconnect and that of said dielectric film are aligned in a same plain.

16. A method of manufacturing a semiconductor device comprising:
forming a dielectric layer on a semiconductor substrate by forming a porous film and forming thereon a non-porous film having a substantially same composition as said porous film;
selectively removing a portion of said dielectric film to form a recess;
forming a metal layer so as to fill said recess; and
performing either polishing or etch-back of said metal layer to an extent that said porous film is not exposed, to remove said metal layer formed outside said recess.

17. The method as set forth in claim 16, wherein said forming said dielectric film includes forming said dielectric film in an integrated process without taking said substrate out of a CVD deposition chamber; and employing a deposition gas containing a template during a process of forming a porous portion of said dielectric film and employing a deposition gas not substantially containing a template during a process of forming a non-porous portion of the same.

18. A method of manufacturing a semiconductor device comprising:
forming a dielectric layer on a semiconductor substrate by forming a porous film containing Si, O and C and forming thereon a non-porous film containing Si, O and C;
selectively removing a portion of said dielectric film to form a recess;
forming a metal layer so as to fill said recess; and
performing either polishing or etch-back of said metal layer to an extent that said porous film is not exposed, to remove said metal layer formed outside said recess.

19. The method as set forth in claim 18, wherein said forming said dielectric film includes forming said dielectric film in an integrated process without taking said substrate out of a CVD deposition chamber; and employing a deposition gas containing a template during a process of forming a porous portion of said dielectric film and employing a deposition gas not substantially containing a template during a process of forming a non-porous portion of the same.

20. A method of manufacturing a semiconductor device comprising forming a porous-structured dielectric film having a substantially uniform composition on a semiconductor substrate; wherein said forming said dielectric film includes controlling a deposition condition to vary a density of pores.

21. The method as set forth in claims 20, wherein said forming said dielectric film includes performing CVD process and changing a deposition gas to vary a density of pores.

22. The method asset forth in claim 20, wherein said forming said dielectric film includes controlling a deposition condition such that said pores are distributed in a relatively lower density in the proximity of an upper surface of said dielectric film.

23. The method as set forth in claim 20, wherein said forming said dielectric film includes forming said dielectric film in an integrated process without taking said substrate out of a CVD deposition chamber; and employing a deposition gas containing a template during a process of forming a porous portion of said dielectric film and employing a deposition gas not substantially containing a template during a process of forming a non-porous portion of the same.

24. A method of manufacturing a semiconductor device comprising:
forming a dielectric film on a semiconductor substrate by forming a first film containing a template and forming a second film not containing a template in this sequence;
selectively removing a portion of said dielectric film to form a recess; and
performing heat treatment on said first film to decompose or remove said template, thereby forming a porous structure in said dielectric film.

25. The method asset forth in claim 24, further comprising:
forming a metal layer so as to fill said recess; and
performing either polishing or etch-back of said metal layer until a surface of said dielectric film is exposed, to remove said metal layer formed outside said recess.

26. The method as set forth in claim 24, wherein said forming said dielectric film includes forming said dielectric film in an integrated process without taking said substrate out of a CVD deposition chamber; and employing a deposition gas containing a template during a process of forming a porous portion of said dielectric film and employing a deposition gas not substantially containing a template during a process of forming a non-porous portion of the same.
